(19) United States
(12) Patent Application Publication
(10) Pub. No.: US 2026/0036912 A1
(43) Pub. Date: Feb. 5, 2026

(54) LITHOGRAPHY SYSTEM AND METHOD FOR OPERATING A LITHOGRAPHY SYSTEM

(71) Applicant: Carl Zeiss SMT GmbH, Oberkochen (DE)

(72) Inventors: Stefan WALZ, Schwaebisch Gmuend (DE); Markus HOLZ, Aalen (DE); Oliver HERBST, Aalen (DE); Steffen VAAS, Ellwangen (DE)

(21) Appl. No.: 19/354,653

(22) Filed: Oct. 9, 2025

Related U.S. Application Data
(63) Continuation of application No. PCT/EP2024/059584, filed on Apr. 9, 2024.

(30) Foreign Application Priority Data
Apr. 13, 2023 (DE) 10 2023 203 338.0

(51) Int. Cl. G03F 7/00

(52) U.S. Cl. CPC G03F 7/702; G03F 7/70033; G03F 7/7085

(57) ABSTRACT

A lithography system comprises: a radiation source for generating radiation having a specific repetition frequency; a mirror which is movable through a tilt angle for guiding the radiation in the lithography system; a measuring device which is designed to measure the tilt angle of the mirror based on a measurement signal having a measurement-signal frequency that is greater than the repetition frequency, in order to provide a time-discrete tilt-angle signal; and an analysis unit which is designed to discard specific signal values of the provided tilt-angle signal on the basis of a signal indicating the points in time at which the radiation impinged on the mirror surface of the mirror in order to provide a corrected time-discrete tilt-angle signal, and in order to determine the position of the mirror based on the corrected time-discrete tilt-angle signal.

### CROSS-REFERENCE TO RELATED APPLICATIONS

The present application is a continuation of, and claims benefit under 35 USC 120 to, international application No. PCT/EP2024/059584, filed Apr. 9, 2024, which claims benefit under 35 USC 119 of German Application No. 10 2023 203 338.0, filed Apr. 13, 2023. The entire disclosure of each of these applications is incorporated by reference herein.

### FIELD

The present disclosure relates to a lithography apparatus and to a method for operating a lithography apparatus.

### BACKGROUND

Microlithography is used to produce microstructured components, for example integrated circuits. The microlithography process is performed using a lithography apparatus that comprises an illumination system and a projection system. The image of a mask (reticle) illuminated via the illumination system is projected via the projection system onto a substrate, for example a silicon wafer, which is coated with a light-sensitive layer (photoresist) and is arranged in the image plane of the projection system, in order to transfer the mask structure to the light-sensitive coating of the substrate.

Driven by a general desie for ever smaller structures in the production of integrated circuits, EUV lithography apparatuses that use light at a wavelength in the range from 0.1 nm to 30 nm, such as 13.5 nm, are currently under development. Since most materials absorb light at this wavelength, such EUV lithography apparatuses typically use reflective optical units, i.e. mirrors, instead of refractive optical units, i.e. lens elements, as used previously.

The use of what are referred to as MEMS mirrors in an illumination system of a lithography apparatus is known. “MEMS” stands for “microelectromechanical system”. Such MEMS mirrors comprise what is known as a micromirror (also referred to as mirror plate) and an actuator. The actuator allows the alignment of the micromirror to be changed. During operation of the lithography apparatus, radiation (also referred to as operating light, for example EUV light) is incident on the surface of the micromirror and is reflected there. Changing the alignment of the micromirror makes it possible to influence the path taken by the EUV light through the illumination system. Such MEMS mirrors are generally manufactured on a substrate in integrated fashion. Typically, such systems use only little installation space. There are often considerable limitations on the installation space for electronic components in a region behind the MEMS mirrors, i.e. on the side facing away from the operating light.

The micromirrors may be e.g. secured to a carrier plate and be configured to be at least partially manipulable or tiltable in order to allow a movement of a respective micromirror in up to six degrees of freedom and hence allow a highly accurate positioning of the micromirrors in relation to one another, for example in the pm range. This can allow changes in the optical properties that occur for instance during the operation of the lithography apparatus, e.g. as a result of thermal influences, to be corrected.

For the purposes of displacing the micromirrors, for example in the six degrees of freedom, actuators that are actuated by way of a control loop are assigned to the micromirrors. A device for monitoring the tilt angle of a respective mirror is provided as part of the control loop.

For example, WO 2009/100856 A1 discloses a facet mirror that is for a projection exposure apparatus of a lithography apparatus and comprises a multiplicity of individually displaceable individual mirrors. To ensure the optical quality of a projection exposure apparatus, relatively precise positioning of the displaceable individual mirrors is involved. Furthermore, document DE 10 2013 209 442 A1 describes that the field facet mirror may take the form of a microelectromechanical system (MEMS).

### SUMMARY

The photons from the EUV radiation source in the lithography apparatus may trigger the emission of electrons from the mirror surfaces of the MEMS mirrors as a result of the photoelectric effect. This may bring about temporally and spatially varying current flows over the MEMS mirrors of the field facet mirror. These temporally and spatially varying current flows over the MEMS mirrors may significantly disturb the monitoring of the tilt angle of the respective MEMS mirror.

The present disclosure seeks to develop an improved lithography apparatus.

According to a first aspect, a lithography apparatus comprises:
a radiation source for generating radiation having a specific repetition frequency,
a mirror that can be displaced through a tilt angle for guiding the radiation within the lithography apparatus,
a detection device that is configured to detect the tilt angle of the mirror based on a measurement signal having a measurement signal frequency that is greater than the repetition frequency, in order to provide a time-discrete tilt angle signal, and
an evaluation unit that is configured to discard specific signal values of the provided tilt angle signal on the basis of a signal that indicates the times of incidence of the radiation on the mirror surface of the mirror in order to provide a filtered time-discrete tilt angle signal and to determine the position of the mirror based on the filtered time-discrete tilt angle signal.

In the present lithography apparatus, the measurement signal frequency of the measurement signal for detecting the tilt angle of the mirror is typically greater, for example greater by at least a factor of 2, than the repetition frequency of the radiation source, for example an EUV radiation source. By virtue of the measurement signal frequency being greater than the repetition frequency of the radiation source, the time-discrete tilt angle signal provided by the detection device can have more signal values than is used for determining the position of the mirror. It is thus possible to discard a subset of the signal values of the time-discrete tilt angle signal. In the present case, the evaluation unit can discard those signal values (the specific signal values) of the provided time-discrete tilt angle signal whose assigned detection times correspond to the times of incidence of the radiation on the surface of the mirror. The respective detection time is one of the times at which the detection device acquires a signal value of the tilt angle signal, for example by sampling.

The times at which the radiation from the radiation source in the lithography apparatus is incident on the mirror surface are those times at which the aforementioned temporally and spatially varying current flows might occur over the MEMS mirrors. In the present case, precisely this subset of the specific signal values of the provided tilt angle signal can be discarded in order to provide a time-discrete tilt angle signal from which this subset has been filtered out. The position of the mirror can then be determined on the basis of the filtered time-discrete tilt angle signal. When the filtered time-discrete tilt angle signal precisely does not comprise the specific disturbed signal values, the determination of the position of the mirror can be significantly more precise in the present case. The more precise determination of the tilt angle significantly generally improves the control loop for the actuation of the actuators of the micromirrors.

The signal that indicates the times of incidence of the radiation on the mirror surface of the mirror may also be referred to as a synchronization signal. For example, the synchronization signal indicates which signal values of the provided tilt angle signal should be discarded in the present case. In the present case, these signal values are also referred to as the specific signal values of the provided tilt angle signal.

The lithography apparatus or projection exposure apparatus may be an EUV lithography apparatus. EUV stands for “extreme ultraviolet” and denotes a wavelength of the operating light between 0.1 nm and 30 nm. The lithography apparatus or projection exposure apparatus may also be a DUV lithography apparatus. DUV stands for “deep ultraviolet” and denotes a wavelength of the operating light of between 30 nm and 250 nm. The guided radiation may be EUV or DUV light.

According to an embodiment, the measurement signal frequency is greater than the repetition frequency of the radiation source by at least a factor of 2.

According to an embodiment, the measurement signal frequency is greater than the repetition frequency by at least a factor of 3, such as by at least a factor of 4, for example by at least a factor of 6.

According to an embodiment, the evaluation unit is configured to discard those signal values of the time-discrete tilt angle signal whose assigned detection times correspond to the times of incidence of the radiation on the surface of the mirror on the basis of the signal that indicates the times of incidence of the radiation on the mirror surface of the mirror in order to provide the filtered time-discrete tilt angle signal.

According to an embodiment, the mirror is a MEMS mirror. The MEMS mirror can have a mirror plate that can be displaced through the tilt angle, a carrier plate for carrying the mirror plate, a base plate, a flexure that couples the carrier plate and the base plate and a capacitive sensor of the detection device arranged between the carrier plate and the base plate.

According to an embodiment, the capacitive sensor is configured to measure the tilt angle of the mirror plate of the MEMS mirror, with the electrodes of the capacitive sensor being of comb-shaped form and arranged in meshed fashion.

According to an embodiment, the comb-shaped electrodes of the capacitive sensor each have a cutout through which the flexure that couples the carrier plate and the base plate is guided.

For example, the flexure is guided through the two cutouts of the comb-shaped electrodes of the capacitive sensor and hence connects the carrier plate and the base plate of the MEMS mirror. The mirror plate of the MEMS mirror can be tilted through the tilt angle by way of the flexure.

According to an embodiment, the lithography apparatus comprises a voltmeter for measuring the voltage drop between the carrier plate and the base plate. In this context, the detection device is configured to detect the tilt angle of the mirror plate based on the measurement signal for providing the time-discrete tilt angle signal. The evaluation unit can be configured to discard the respective signal value of the provided time-discrete tilt angle signal in order to provide the filtered time-discrete tilt angle signal should the measured voltage at the detection time assigned to the respective signal value be greater than a predetermined threshold value. Furthermore, the evaluation unit can be configured to determine the position of the mirror plate based on the filtered time-discrete tilt angle signal.

In the present embodiment, the measured voltage drop between the carrier plate and the base plate can form the signal that indicates the times of incidence of the radiation on the mirror surface of the mirror since the times at which the radiation from the radiation source is incident on the mirror surface and may thus lead to disturbances when acquiring the tilt angle signal can be derived from this measured voltage by using the predetermined threshold value. Thus, should the measured voltage be greater than the predetermined threshold value at a specific detection time assigned to a specific signal value of the time-discrete tilt angle signal, this signal value of the time-discrete tilt angle signal can be discarded in order to provide the correspondingly filtered time-discrete tilt angle signal for determining the position of the mirror.

According to an embodiment, the lithography apparatus comprises a micromirror array that comprises a plurality of MEMS mirrors.

According to an embodiment, the lithography apparatus comprises a photodiode for providing a photocurrent proportional to the radiation incident on the mirror plate of the MEMS mirror. In this context, the detection device can be configured to detect the tilt angle of the mirror plate based on the measurement signal for providing the time-discrete tilt angle signal. The evaluation unit can be configured to discard the respective signal value of the provided time-discrete tilt angle signal in order to provide the filtered time-discrete tilt angle signal should the provided photocurrent at the detection time assigned to the respective signal value be greater than a predetermined threshold value.

In the present embodiment, the photocurrent provided by the photodiode can form the signal that indicates the times of incidence of the radiation on the mirror surface of the mirror. Should the provided photocurrent be greater than a predetermined threshold value at a specific detection time that is assigned a specific signal value of the provided time-discrete tilt angle signal, this specific signal value of the provided tilt angle signal can be discarded in order to provide the correspondingly filtered time-discrete tilt angle signal for determining the position of the mirror.

According to an embodiment, the lithography apparatus comprises a micromirror array that comprises a plurality of MEMS mirrors and the photodiode. For example, the plurality of MEMS mirrors are arranged in a matrix-like manner in the array. At least one element of this matrix can be occupied by the photodiode rather than by a MEMS mirror.

According to an embodiment, the lithography apparatus comprises a vacuum housing in which the radiation source, the mirror, the detection device and the evaluation unit are arranged. For example, the vacuum housing is designed for a pressure of 1013.25 hPa to 10⁻³ hPa, such as 10⁻³ to 10⁻⁸ hPa, and for example 10⁻⁸ to 10⁻¹¹ hPa in its interior.

According to an embodiment, the lithography apparatus comprises a controller arranged externally to the vacuum housing and serving to control the radiation source based on a control signal. In this case, the evaluation unit can be configured to discard the specific signal values of the acquired time-discrete tilt angle signal on the basis of the control signal or on the basis of a synchronization signal derived from the control signal in order to provide the filtered time-discrete tilt angle signal.

In the present embodiment, the control signal or the synchronization signal derived from the control signal can form the signal that indicates the times of incidence of the radiation on the mirror surface of the mirror. On the basis of the control signal and/or on the basis of the synchronization signal, the evaluation unit can decide which signal values of the provided tilt angle signal should be discarded, namely those signal values whose detection times correspond to the times at which radiation from the radiation source in the lithography apparatus is incident on the mirror surface of the mirror.

According to an embodiment, the mirror, the detection device and the evaluation unit are arranged in an illumination system of the lithography apparatus.

According to an embodiment, the radiation source is an EUV radiation source.

The respective unit, for example the control unit, may be implemented in hardware and/or software. In a hardware implementation, the unit may be designed as a device or as part of a device, for example as a computer or as a microprocessor or as part of the controller. In a software implementation, the unit may be designed as a computer program product, as a function, as a routine, as part of a program code or as an executable object.

According to a second aspect, the disclosure provides a method for operating a lithography apparatus. The lithography apparatus comprises a radiation source for generating radiation having a specific repetition frequency, a mirror that can be displaced through a tilt angle for guiding the radiation within the lithography apparatus and a detection device for detecting the tilt angle. The method includes:
detecting the tilt angle of the mirror during the operation of the lithography apparatus by the detection device based on a measurement signal having a measurement signal frequency that is greater than the repetition frequency in order to provide a time-discrete tilt angle signal,
discarding specific signal values of the provided tilt angle signal on the basis of a signal that indicates the times of incidence of the radiation on the mirror surface of the mirror in order to provide a filtered time-discrete tilt angle signal, and
determining the position of the mirror based on the filtered time-discrete tilt angle signal.

The embodiments described for the proposed lithography apparatus according to the first aspect apply accordingly to the proposed method according to the second aspect. Furthermore, the definitions and explanations given in relation to the system also apply accordingly to the proposed method.

“A(n)” should not necessarily be understood as a restriction to exactly one element in the present case. Instead, there may also be provision for multiple elements, for example two, three or more. Any other numeral used here should also not be understood as a restriction to exactly the stated number of elements. Rather, unless indicated otherwise, numerical variances upward and downward are possible.

Further possible implementations of the disclosure also comprise combinations not explicitly mentioned of features or embodiments described hereinabove or hereinafter with regard to the exemplary embodiments. A person skilled in the art will also add individual aspects as improvements or supplementations to the respective basic form of the disclosure.

Various configurations and aspects of the disclosure are the subject of the claims and of the exemplary embodiments of the disclosure that are described hereinafter. The disclosure is elucidated in greater detail hereinafter on the basis of certain embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic view of a first embodiment of an aspect of the lithography apparatus;

FIG. 3 shows one example of an extract of the plot of the time-discrete tilt angle signal provided by the detection device of FIG. 2;

FIG. 4 shows one example of an extract of the plot of the voltage measured by the voltmeter of FIG. 2;

FIG. 5 shows one example of an extract of the plot of the filtered tilt angle signal provided by the evaluation unit of FIG. 2;

FIG. 6 shows a schematic view of a second embodiment of an aspect of the lithography apparatus;

FIG. 7 shows a schematic view of a third embodiment of an aspect of the lithography apparatus; and

FIG. 8 shows one embodiment of a method for operating a lithography apparatus.

### DETAILED DESCRIPTION

In the figures, identical or functionally identical elements have been provided with the same reference signs, unless indicated otherwise. Further, it should be noted that the representations in the figures are not necessarily true to scale.

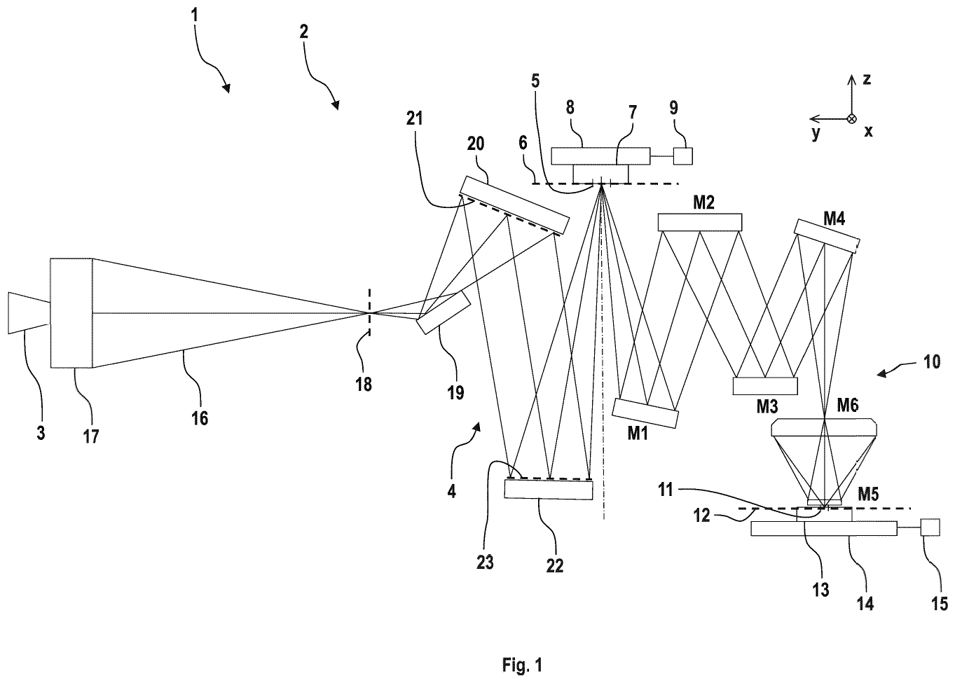

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, by way of elucidation, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optics unit 10. The projection optics unit 10 serves to image the object field 5 into an image field 11 in an image plane 12. The image plane 12 runs parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement, firstly, of the reticle 7 by way of the reticle displacement drive 9 and, secondly, of the wafer 13 by way of the wafer displacement drive 15 can be implemented so as to be in sync with one another.

The light source 3 is an EUV radiation source. The light source 3 emits for example EUV radiation 16, which is also referred to below as used radiation, illumination radiation or illumination light. The used radiation 16 has for example a wavelength in the range between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector having one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, comprising the light source 3 and the collector 17, and the illumination optics unit 4.

The illumination optics unit 4 comprises a deflection mirror 19 and, arranged downstream thereof in the beam path, a first facet mirror 20. The deflection mirror 19 may be a planar deflection mirror or alternatively a mirror with a beam-influencing effect going beyond the pure deflection effect. In an alternative to that or in addition, the deflection mirror 19 may take the form of a spectral filter that separates a used light wavelength of the illumination radiation 16 from extraneous light of a wavelength differing therefrom. Should the first facet mirror 20 be arranged in a plane of the illumination optics unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may take the form of macroscopic facets, for example the form of rectangular facets or the form of facets with an arcuate or partly circular peripheral contour. The first facets 21 may take the form of planar facets or, alternatively, convexly or concavely curved facets.

As is known for example from DE 10 2008 009 600 A1, the first facets 21 themselves may also be composed in each case of a multiplicity of individual mirrors, for example a multiplicity of micromirrors. The first facet mirror 20 may take the form of a microelectromechanical system (MEMS system) for example. For details, reference is made to DE 10 2008 009 600 A1.

The illumination radiation 16 travels horizontally, i.e. in the y-direction y, between the collector 17 and the deflection mirror 19.

In the beam path of the illumination optics unit 4, a second facet mirror 22 is disposed downstream of the first facet mirror 20. If the second facet mirror 22 is arranged in a pupil plane of the illumination optics unit 4, it is also referred to as a pupil facet mirror.

The second facet mirror 22 may also be arranged at a distance from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may also be macroscopic facets, which may for example have a round, rectangular or hexagonal boundary, or may alternatively be facets composed of micromirrors. In this regard, reference is also made to DE 10 2008 009 600 A1.

The second facets 23 may have planar or, alternatively, convexly or concavely curved reflection surfaces.

The illumination optics unit 4 thus forms a doubly faceted system. This fundamental principle is also referred to as a fly's eye integrator.

It may be advantageous to arrange the second facet mirror 22 not exactly in a plane that is optically conjugate to a pupil plane of the projection optical unit 10. For example, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In an embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may comprise exactly one mirror, or alternatively two or more mirrors, which are arranged one behind the other in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20 and the second facet mirror 22.

In another embodiment of the illumination optics unit 4, the deflection mirror 19 may also be omitted, and so the illumination optics unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is, as a rule, only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are also possible. The projection optics unit 10 is a doubly obscured optical unit. The penultimate mirror M5 and the last mirror M6 each have a passage opening for the illumination radiation 16. The projection optics unit 10 has an image-side numerical aperture that is greater than 0.5 and may also be greater than 0.6 and for example may be 0.7 or 0.75.

Reflection surfaces of the mirrors Mi may take the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, for example with alternating layers of molybdenum and silicon.

The projection optics unit 10 has a large object-image shift in the y-direction y between a y-coordinate of a center of the object field 5 and a y-coordinate of the center of the image field 11. This object-image shift in the y-direction y may be of approximately the same magnitude as a z-distance between the object plane 6 and the image plane 12.

The projection optics unit 10 may for example have an anamorphic form. For example, it has different imaging scales βx, βy in the x- and y-directions x, y. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are also possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optics unit 10. Examples of projection optics units with different numbers of such intermediate images in the x-direction x and y-direction y are known from US 2018/0074303 A1.

In each case one of the second facets 23 is assigned to exactly one of the first facets 21 in order to form a respective illumination channel for illuminating the object field 5. This may for example produce illumination according to the Köhler principle. The far field is decomposed into a multiplicity of object fields 5 using the first facets 21. The first facets 21 generate a plurality of images of the intermediate focus on the second facets 23 respectively assigned to them.

By way of an assigned second facet 23, the first facets 21 are each imaged onto the reticle 7 and overlaid on one another for the purpose of illuminating the object field 5. The illumination of the object field 5 is for example of maximum homogeneity. It can have a uniformity error of less than 2%. Field uniformity can be achieved by overlaying different illumination channels.

An arrangement of the second facets 23 may geometrically define the illumination of the entrance pupil of the projection optics unit 10. The intensity distribution in the entrance pupil of the projection optics unit 10 may be set by selecting the illumination channels, for example the subset of the second facets 23 that guide light. This intensity distribution is also referred to as illumination setting or illumination pupil filling.

A likewise preferred pupil uniformity in the region of portions of an illumination pupil of the illumination optics unit 4 which are illuminated in a defined manner may be achieved by a redistribution of the illumination channels.

Further aspects and details of the illumination of the object field 5 and, for example, of the entrance pupil of the projection optics unit 10 are described below.

The projection optics unit 10 may have for example a homocentric entrance pupil. The latter may be accessible. It may also be inaccessible.

The entrance pupil of the projection optics unit 10 regularly cannot be exactly illuminated with the second facet mirror 22. In the case of imaging by the projection optics unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optics unit 10 has different positions of the entrance pupil for the tangential beam path and for the sagittal beam path. In this case, an imaging element, for example an optical structural element of the transfer optics unit, should be provided between the second facet mirror 22 and the reticle 7. This optical element can be used to take into account the different position of the tangential entrance pupil and the sagittal entrance pupil.

In the arrangement of the components of the illumination optics unit 4 shown in FIG. 1, the second facet mirror 22 is arranged in an area conjugate to the entrance pupil of the projection optics unit 10. The first facet mirror 20 is arranged so as to be tilted with respect to the object plane 6. The first facet mirror 20 is arranged so as to be tilted with respect to an arrangement plane defined by the deflection mirror 19. The first facet mirror is arranged so as to be tilted with respect to an arrangement plane defined by the second facet mirror 22.

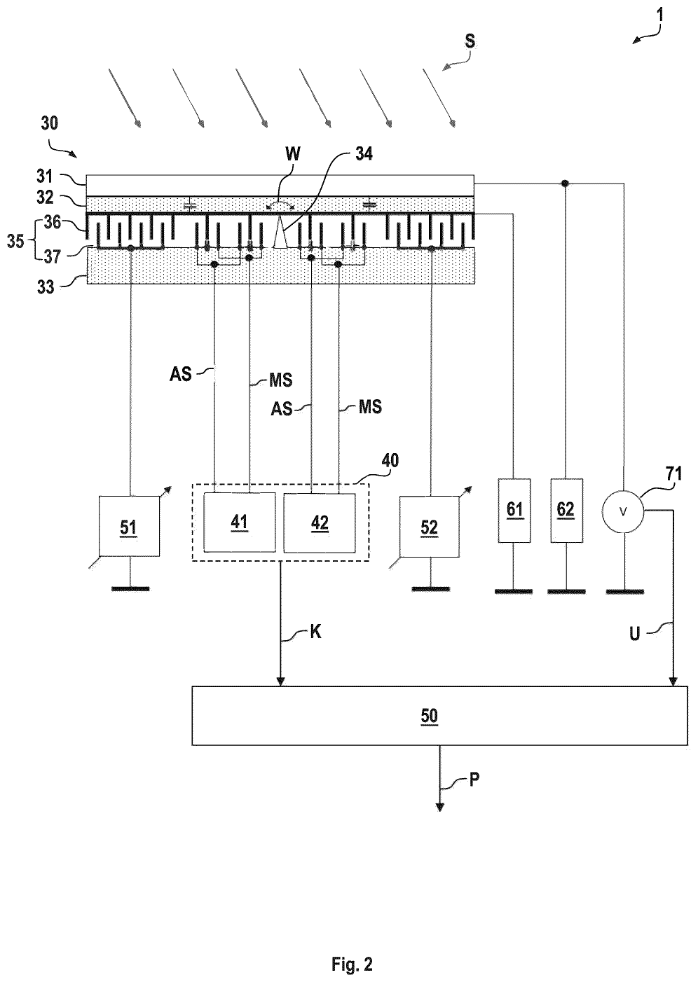

FIG. 2 shows a schematic view of a first embodiment of one aspect of a lithography apparatus or projection exposure apparatus 1, as shown in FIG. 1, for example.

In this case, FIG. 2 shows the radiation S that is generated by the radiation source 3 in the lithography apparatus 1 according to FIG. 1 and has a specific repetition frequency. Furthermore, FIG. 2 shows a mirror 30 that can be displaced through a tilt angle W for guiding the radiation S within the lithography apparatus 1. The mirror 30 may take the form of a MEMS mirror in order, for example, to be part of one of the mirrors 20, 22, M1-M6 in the lithography apparatus 1 of FIG. 1.

The MEMS mirror 30 has a mirror plate 31 that can be displaced through the tilt angle W, a carrier plate 32 for carrying the mirror plate 31, a base plate 33, a flexure 34 that couples the carrier plate 32 and the base plate 33 and a capacitive sensor 35 of a detection device 40 arranged between the carrier plate 32 and the base plate 33. The detection device 40 is configured to detect the tilt angle W of the MEMS mirror 30 based on a measurement signal MS having a measurement signal frequency, in order to provide a time-discrete tilt angle signal K. The measurement signal frequency is greater than the repetition frequency. For example, the measurement signal frequency is greater than the repetition frequency by at least a factor of 2.

The MEMS mirror 30 is displaceable for example about two tilt axes, such as about two tilt axes that are orthogonal to each other. Here, the sectional view of the MEMS mirror in FIG. 2 shows a tilt axis. The detection device 40 of FIG. 2 comprises the aforementioned capacitive sensor 35 and two sensor units 41 and 42 per tilt axis. The capacitive sensor 35 is configured to measure the tilt angle W of the mirror plate 31 of the MEMS mirror 30. The electrodes 36, 37 of the capacitive sensor 35 are of comb-shaped form and arranged in meshed fashion with respect to one another. In this context, the capacitive sensor 35 comprises an upper electrode 36 that is coupled to the carrier plate 32. Furthermore, the capacitive sensor 35 comprises a lower electrode 37 that is coupled to the base plate 33. The respective sensor unit 41, 42 is configured to excite the capacitive sensor 35 based on an excitation signal AS and receive the measurement signal MS in response thereto.

For the purpose of actuating the MEMS mirror 30, two control units 51, 52 are provided per tilt axis. The upper electrode 36 of the capacitive sensor 35 is coupled to ground via the resistor 61. Further, the mirror plate 31 is coupled to ground via the resistor 62.

As already explained above, the detection device 40 provides a time-discrete tilt angle signal K at the output. The time-discrete tilt angle signal K is supplied to an evaluation unit 50. The evaluation unit 50 is configured to discard specific signal values of the provided tilt angle signal K on the basis of a signal U that indicates the times of incidence of the radiation S on the mirror surface of the MEMS mirror 30 in order to provide a filtered time-discrete tilt angle signal B and to then determine the position P of the MEMS mirror 30 based on the filtered time-discrete tilt angle signal B.

In this context, the evaluation unit 50 is configured for example to discard those signal values of the time-discrete tilt angle signal K whose assigned detection times correspond to the times of incidence of the radiation S on the mirror surface of the MEMS mirror 30 on the basis of the signal U that indicates the times of incidence of the radiation S on the mirror surface of the MEMS mirror 30 in order to provide the filtered time-discrete tilt angle signal B.

FIGS. 2, 6 and 7 show various embodiments with regard to the signal that indicates the times of incidence of the radiation S on the mirror surface of the MEMS mirror 30.

In the example of FIG. 2, the measured voltage U drop between the carrier plate 31 and the base plate 33, which is connected to ground, forms this signal that indicates the times of incidence of the radiation S on the mirror surface of the MEMS mirror 30. From this measured voltage U, it is possible to derive the times at which the radiation S from the radiation source 3 is incident on the mirror surface of the MEMS mirror 30 and may thus lead to disturbances when acquiring the tilt angle signal K.

A voltmeter 71 coupled between the mirror plate 31 and ground is provided to measure the voltage U drop between the mirror plate 31 and the base plate 33. Since the base plate 33 is also grounded (not shown), the voltmeter 71 may naturally also be connected between the mirror plate 31 and the base plate 33.

The evaluation unit 50 of FIG. 2 receives the time-discrete tilt angle signal K provided by the detection device 40 and the voltage U measured by the voltmeter 71. In this case, the evaluation unit 50 is configured to discard the respective signal value of the provided time-discrete tilt angle signal K in order to provide the filtered time-discrete tilt angle signal B should the measured voltage U at the detection time assigned to the respective signal value be greater than a predetermined threshold value T1 (see FIG. 4). Then, the evaluation unit 50 is able to determine the position P of the mirror plate 31 based on the filtered time-discrete tilt angle signal B.

The mirror 30, the detection device 40 and the evaluation unit 50 are arranged for example in the illumination system 2 (cf. FIG. 1) of the lithography apparatus 1. The radiation source 3 is an EUV radiation source for example.

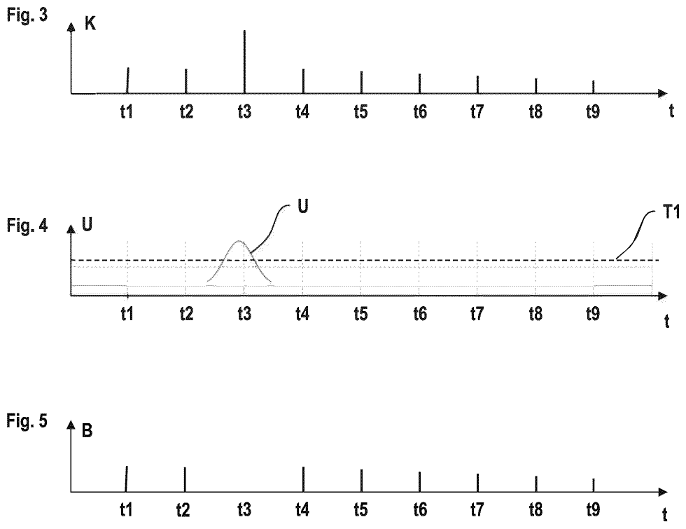

FIGS. 3 to 5 show an example of filtering the tilt angle signal K and the associated provision of the filtered tilt angle signal B. In this context, FIG. 3 shows one example of an extract of the plot of the time-discrete tilt angle signal K as provided by the detection device 40. FIG. 4 shows one example of an extract of the plot of the voltage U as measured by the voltmeter 71, and FIG. 5 shows one example of an extract of the plot of the filtered tilt angle signal B.

The x-axes in FIGS. 3, 4 and 5 plot the time and are identical. The y-axis in FIG. 3 plots the amplitude of the time-discrete tilt angle signal K, the y-axis in FIG. 4 plots the amplitude of the measured voltage U, and the y-axis in FIG. 5 plots the amplitude of the filtered tilt angle signal B.

According to FIG. 4, the measured voltage U at the time t3 is greater than the predetermined threshold value T1. At all other times t1, t2 and t4 to t9, the measured voltage U is lower than the predetermined threshold value T1. Following the condition that a signal value of the provided time-discrete tilt angle signal K, as shown in FIG. 3, is discarded when the measured voltage U at the detection time assigned to the respective signal value of the time-discrete tilt angle signal K is greater than the threshold value T1, only the signal value of the time-discrete tilt angle signal K in FIG. 3 at the time t3 is discarded. Consequently, the filtered tilt angle signal B in FIG. 5 is created from the tilt angle signal K in FIG. 3 excluding the signal value at the time t3 as this signal value was discarded on account of the threshold value T1 being exceeded.

As the various signal values at the times t1 to t9 in FIG. 3 show, the signal value at the time t3 has a significantly larger amplitude, this being caused by the disturbance due to the radiation S on the mirror surface and the associated emitted electrons, and is thus discarded according to the above condition, and so the position determination on the basis of the filtered tilt angle signal B is more precise than on the basis of the tilt angle signal K.

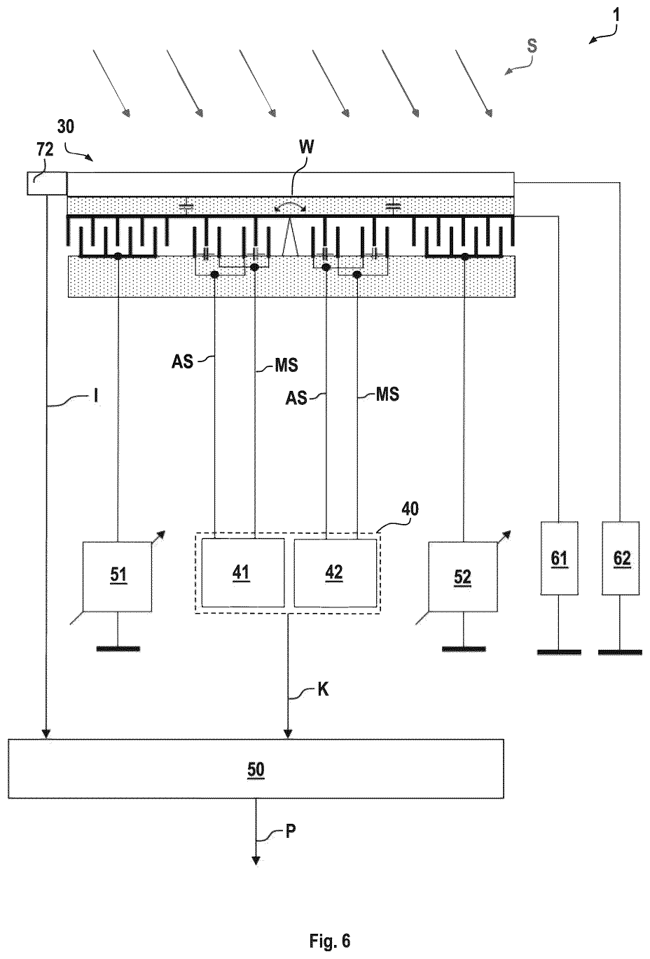

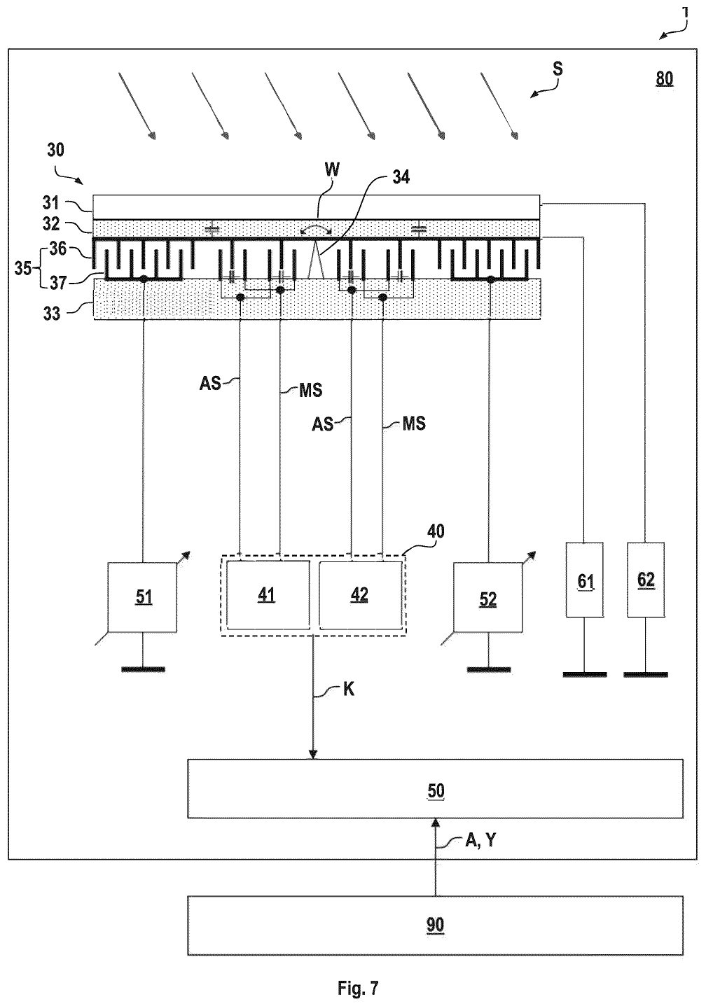

FIG. 6 depicts a schematic view of a second embodiment of one aspect of a lithography apparatus or projection exposure apparatus 1, as shown in FIG. 1, for example. The second embodiment according to FIG. 6 differs from the first embodiment according to FIG. 2 for example in terms of the form of the signal that indicates the times of incidence of the radiation S on the mirror surface of the mirror 30.

In the second embodiment according to FIG. 6, a photocurrent I proportional to the radiation S incident on the mirror plate 31 of the MEMS mirror 30 is used for this purpose. To this end, at least one photodiode 72 is provided in the second embodiment according to FIG. 6 and configured to provide the photocurrent I proportional to the radiation S incident on the mirror plate 31 of the MEMS mirror 30. In this context, it should be noted that the lithography apparatus 1 may comprise a micromirror array that may comprise a plurality of MEMS mirrors 30, as illustrated in FIG. 6, and a number of photodiodes 72.

The mirror plate 31, the carrier plate 32, the base plate 33, the flexure 34 and the capacitive sensor 35 with the upper comb-shaped electrode 36 and the lower comb-shaped electrode 37 correspond to those in FIG. 2. Therefore, and for reasons of clarity, reference signs 31 to 37 have been omitted in FIG. 6.

According to FIG. 6, the photocurrent I provided by the photodiode 72 and the time-discrete tilt angle signal K provided by the detection device 40 are supplied to the evaluation unit 50. In this case, the evaluation unit 50 is configured to discard the respective signal value of the provided time-discrete tilt angle signal K in order to provide the filtered time-discrete tilt angle signal B should the provided photocurrent I at the detection time assigned to the respective signal value be greater than a predetermined threshold value. Ultimately, this operates as illustrated in FIG. 3-5, albeit not by using the voltage U drop between the mirror plate 31 and the base plate 33 but rather based on the photocurrent I that is proportional to the radiation S incident on the mirror plate 31.

FIG. 7 shows a schematic view of a third embodiment of one aspect of a lithography apparatus or projection exposure apparatus 1, as shown in FIG. 1, for example.

The third embodiment according to FIG. 7 differs from the first embodiment according to FIG. 2 and the second embodiment according to FIG. 6 in terms of the configuration of the signal that indicates the times of incidence of the radiation S on the mirror surface of the mirror 30. In accordance with FIG. 7, the lithography apparatus 1 has a vacuum housing 80, in which the radiation source 3 (not illustrated in FIG. 7, cf. FIG. 1), the mirror 30, the detection device 40 and the evaluation unit 50 are arranged. Further, the lithography apparatus 1 according to FIG. 7 has a controller 90 arranged externally to the vacuum housing 80 and serving to control the radiation source 3 based on a control signal A.

According to FIG. 7, the evaluation unit 50 is configured to discard the specific signal values of the acquired time-discrete tilt angle signal K on the basis of the control signal A or on the basis of a synchronization signal Y derived from the control signal A in order to provide the filtered time-discrete tilt angle signal B.

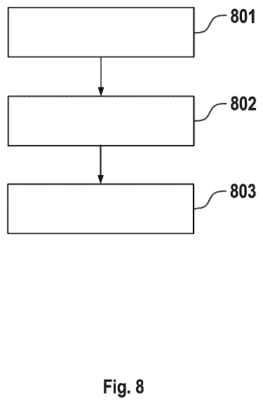

FIG. 8 shows one embodiment of a method for operating a lithography apparatus 1. Examples of such a lithography apparatus 1 are explained with reference to FIGS. 1 to 7. The lithography apparatus 1 has at least a radiation source 3 for generating radiation S having a specific repetition frequency, a mirror 30 that can be displaced through a tilt angle W for guiding the radiation S within the lithography apparatus 1 and a detection device 40 for detecting the tilt angle W.

The method according to FIG. 8 comprises steps 801 to 803:

In step 801, the tilt angle W of the mirror 30 is detected during the operation of the lithography apparatus 1 by the detection device 40 based on a measurement signal MS having a measurement signal frequency that is greater than the repetition frequency of the radiation source 3 in order to provide a time-discrete tilt angle signal K.

In step 802, specific signal values of the provided tilt angle signal K are discarded on the basis of a signal U, I, A, Y that indicates the times of incidence of the radiation S on the mirror surface of the mirror 30 in order to provide a filtered time-discrete tilt angle signal B.

In step 803, the position P of the mirror 30 is determined based on the filtered time-discrete tilt angle signal B.

Although the present disclosure has been described with reference to various embodiments, it is modifiable in a variety of ways.

### LIST OF REFERENCE SIGNS

1 Projection exposure apparatus
2 Illumination system
3 Radiation source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
30 Mirror
31 Mirror plate
32 Carrier plate
33 Base plate
34 Flexure
35 Capacitive sensor
36 Upper comb-shaped electrode
37 Lower comb-shaped electrode
40 Detection device
41 First sensor unit
42 Second sensor unit
50 Evaluation unit
51 Control unit
52 Control unit
61 Resistor
62 Resistor
71 Voltmeter
72 Photodiode
80 Vacuum housing
90 External controller
801-803 Method steps
A Control signal
AS Excitation signal
B Filtered tilt angle signal
I Photocurrent
K Tilt angle signal
M1 Mirror
M2 Mirror
M3 Mirror
M4 Mirror
M5 Mirror
M6 Mirror
MS Measurement signal
P Position of the mirror
T1 Threshold value
S Radiation
U Voltage
W Tilt angle
Y Synchronization signal

What is claimed is:

1. A lithography apparatus, comprising:
a radiation source configured to generate radiation having a repetition frequency;
a MEMS mirror configured to guide the radiation within the lithography apparatus, the MEMS mirror comprising: a mirror plate displaceable through a tilt angle; a carrier plate carrying the mirror plate; a base plate; and a flexure coupling the carrier plate and the base plate;
a photodiode configured to provide a photocurrent proportional to the radiation incident on the mirror plate;
a detection device comprising a capacitive sensor between the carrier plate and the base plate, the capacitive sensor configured to detect the tilt angle of the mirror plate based on a measurement signal having a measurement signal frequency that is greater than the repetition frequency to provide a time-discrete tilt angle signal; and
an evaluation unit configured so that, when the photocurrent at a detection time assigned to a signal value is greater than a threshold value, the evaluation unit discards the signal value of the time-discrete tilt angle signal based on a signal indicating the time of incidence of the radiation on a surface of the MEMs mirror to provide a filtered time-discrete tilt angle signal and to determine a position of the mirror based on the filtered time-discrete tilt angle signal.

2. The lithography apparatus of claim 1, wherein the measurement signal frequency is at least twice the repetition frequency.

3. The lithography apparatus of claim 1, wherein the evaluation unit is configured to discard signal values of the time-discrete tilt angle signal whose detection times correspond to the times of incidence of the radiation on the MEMs mirror surface based on the signal that indicates the times of incidence of the radiation on the MEMs mirror surface to provide the filtered time-discrete tilt angle signal.

4. The lithography apparatus of claim 1, wherein the capacitive sensor is configured to measure the tilt angle of the mirror plate, and the capacitive sensor comprises with comb-shaped electrodes that are enmeshed with each other.

5. The lithography apparatus of claim 4, wherein each comb-shaped electrode has a cutout through which the flexure is guided.

6. The lithography apparatus of claim 1, further comprising a voltmeter configured to measure a voltage drop between the mirror plate and the base plate.

7. The lithography apparatus of claim 6, wherein the lithography apparatus comprises a micromirror array, and the micromirror array comprises a plurality of MEMS mirrors.

8. The lithography apparatus of claim 1, wherein the lithography apparatus comprises a micromirror array, and the micromirror array comprises a plurality of MEMS mirrors.

9. The lithography apparatus of claim 1, wherein the lithography apparatus comprises a micromirror array, and the micromirror array comprises a plurality of MEMS mirrors and the photodiode.

10. The lithography apparatus of claim 1, further comprising a vacuum housing housing the radiation source, the MEMs mirror, the detection device and the evaluation unit.

11. The lithography apparatus of claim 10, further comprising a controller external to the vacuum housing, wherein:
the controller is configured to control the radiation source based on a control signal; and
the evaluation unit is configured to discard the signal values of the time-discrete tilt angle signal based on the control signal or based on a synchronization signal derived from the control signal to provide the filtered time-discrete tilt angle signal.

12. The lithography apparatus of claim 10, comprising an illumination system, wherein the MEMs mirror, the detection device and the evaluation unit are in the illumination system.

13. The lithography apparatus of claim 1, wherein the radiation source comprises an EUV radiation source.

14. The lithography apparatus of claim 1, comprising an illumination system, wherein the MEMs mirror, the detection device and the evaluation unit are in the illumination system.

15. The lithography apparatus of claim 1, further comprising a controller, wherein:
the controller is configured to control the radiation source based on a control signal; and
the evaluation unit is configured to discard the signal values of the time-discrete tilt angle signal based on the control signal or based on a synchronization signal derived from the control signal to provide the filtered time-discrete tilt angle signal.

16. The lithography apparatus of claim 1, wherein:
the measurement signal frequency is at least twice the repetition frequency; and
the evaluation unit is configured to discard signal values of the time-discrete tilt angle signal whose detection times correspond to the times of incidence of the radiation on the MEMs mirror surface based on the signal that indicates the times of incidence of the radiation on the MEMs mirror surface to provide the filtered time-discrete tilt angle signal.

17. The lithography apparatus of claim 16, wherein the capacitive sensor is configured to measure the tilt angle of the mirror plate, and the capacitive sensor comprises with comb-shaped electrodes that are enmeshed with each other.

18. The lithography apparatus of claim 1, wherein:
the measurement signal frequency is at least twice the repetition frequency;
the capacitive sensor is configured to measure the tilt angle of the mirror plate; and
the capacitive sensor comprises with comb-shaped electrodes that are enmeshed with each other.

19. A method, comprising:
providing the lithography apparatus of claim 1; and
using the lithography apparatus to determine a position of the MEMS mirror.

20. A method of operating a lithography apparatus, the lithography apparatus comprising: a radiation source configured to generate radiation having a repetition frequency; a MEMs mirror configured to guide radiation within the lithography apparatus; a photodiode configured to provide a photocurrent proportional to the radiation incident on a mirror plate of the MEMS mirror; and a detection device configured to detect the tilt angle, the MEMS mirror comprising the mirror plate; a carrier plate carrying the mirror plate; a base plate; and a flexure coupling the carrier plate and the base plate, the base plate being displaceable through a tilt angle, the detector comprising a capacitive sensor between the carrier plate and the base plate, the method comprising:
detecting the tilt angle of the mirror plate during the operation of the lithography apparatus based on a measurement signal received by the detection device, the measurement signal having a measurement signal frequency that is greater than the repetition frequency to provide a time-discrete tilt angle signal;
when a photocurrent at the detection time assigned to the respective signal value be greater than a predetermined threshold value, discarding the signal value of the time-discrete tilt angle signal based on a signal indicating the times of incidence of the radiation on a surface of the MEMs mirror o provide a filtered time-discrete tilt angle signal; and
determining a position of the mirror using the filtered time-discrete tilt angle signal.
